(19) United States
(12) Patent Application Publication
(10) Pub. No.: US 2008/0119056 A1
(43) Pub. Date: May 22, 2008

(54) METHOD FOR IMPROVED COPPER LAYER ETCHING OF WAFERS WITH C4 CONNECTION STRUCTURES

(75) Inventors: Carla A. Bailey, Poughkeepsie, NY (US); Tien-Jen Cheng, Bedford, NY (US); Robert Henry, Newburgh, NY (US); Anurag Jain, Poughkeepsie, NY (US); Vall F. McLean, Poughkeepsie, NY (US); Krystyna W. Semkow, Poughquag, NY (US); Kamalesh K. Srivastava, Wappingers Falls, NY (US)

Correspondence Address: CANTOR COLBURN LLP - IBM FISHKILL, 20 Church Street, 22nd Floor, Hartford, CT, 06103, US

(73) Assignee: INTERNATIONAL BUSINESS MACHINES CORPORATION, Armonk, NY (US)

(21) Appl. No.: 11/560,505

(22) Filed: Nov. 16, 2006

(51) Int. Cl. H01L 21/306; C09K 13/04

(52) U.S. Cl. 438/754; 252/79.2; 257/E21.219

(57) ABSTRACT

A solution for wet etching a copper film within a ball limiting metallurgy (BLM) of a semiconductor device includes, in an exemplary embodiment, an ammonium persulfate etching agent, a potassium sulfate passivation agent for protecting a PbSn solder material, and a pH modifier for controlling the etch rate of the copper film.

### BACKGROUND

The present invention relates generally chemical wet etching of metal films in semiconductor applications and, more particularly, to a method for copper layer etching of wafers with Controlled Collapse Chip Connection (C4) connection structures.

Controlled Collapse Chip Connection (C4) is an advanced microelectronic chip packaging and connection technology, which is also referred to as “solder bump” and “flip chip.” The basic idea of C4 is to connect chips, chip packages, or such other units by means of solder balls placed between two surfaces of the units. These tiny balls of electrically conductive solder bridge the gaps between respective pairs of metal pads on the units being connected. Each pad has a corresponding pad on the surface of the other unit such that the pad arrangements are mirror images. As the units are aligned and exposed to temperatures above the melting point of the solder, the solder balls on the pads of the first unit become molten and join to corresponding conductive pads on the second unit, thereby making permanent connections between respective pads.

In C4 technology, the solder balls typically are formed directly on the metal pads of one surface. The bumps are electrically isolated from each other by the insulating material that surrounds each ball. The substrate may include, for example, undoped silicon (Si) or other suitable material. The bottom of the solder ball is electrically connected to the chip circuit. When the balls are aligned to metal pads on a second surface and reflowed, the liquid solder bumps wet the receiving pads. Upon cooling, relatively low-stress solder joints are formed. This process allows all of the connections to be made in one step, even with slight variations in the surfaces.

C4 technology allows for a very high density of electrical interconnections. Unlike earlier techniques that make connections around the perimeter of a chip or a chip package, C4 allows one or more surfaces of a chip or package to be packed with pads. The number of possible connections with C4 is roughly the square of the number that is possible with perimeter connection. Because the C4 balls can be made quite small (e.g., less than a hundredth of an inch in diameter), the surface density of C4 connections can be on the order of thousands per square inch.

C4 solder bumps must be sufficiently mechanically secured to their substrates; otherwise, they may fail during the thermal stressing that is characteristic of routine device operation. Accordingly, various interfacial layers are typically placed between the solder bumps and substrate or wafer upon which they are formed. The composition and characteristics of these interfacial layers, commonly referred to as the Ball Limiting Metallurgy or BLM, play an integral role in ensuring acceptable mechanical adhesion of the solder bump to the chip. In addition, these layers often act as a diffusion barrier between the solder and the chip metallurgy, which may be composed of aluminum and/or copper. Without an adequate diffusion barrier, the solder will attack the chip wiring and destroy functionality.

One technique for creating solder bumps is through electrodeposition, also known as electrochemical plating or electroplating. This technique utilizes a preliminary step to form a continuous layer of conductive metal adhered onto the insulating substrate. This layer is typically composed of several metal layers, which serve the additional purpose of forming the BLM metallurgy. Examples of first layers used in this method include chromium (Cr), titanium-tungsten alloys (TiW), or any other metals that adhere well to the substrate. This first metal layer may be on the order of about one ten-thousandth of a millimeter thick. A second layer may then be deposited on top of the first layer, and may be an alloy of chromium-copper (CrCu) or nickel-vanadium (NiV), for example. Finally, a third layer, (e.g., pure copper) which will function as a primary “seed” layer for electrodepositing solder balls is deposited over the other layers. The thickness of the layers may vary, and is typically chosen to optimize the stress-thickness product, diffusion properties, and mechanical integrity.

A second preliminary step, once the seed layer is laid down, is to form a mask by photolithography. A layer of photoresist is laid onto the Cu seed layer and exposed to light so as to cure the exposed photoresist. The unexposed photoresist remains uncured and is then washed away to leave the cured photoresist behind as a mask that includes rows of holes corresponding to locations where the solder bumps are to be deposited. The third step is electrodeposition (electroplating) of lead or other solder alloy into the mask holes. An electrodeposited solder bump might be about 0.25 millimeters (mm) high and contain a small amount of tin (Sn), and will thus adhere well to the uppermost copper layer. Upon reflow, copper and tin react to form an intermetallic layer, CuₓSn_{y} (for example, Cu₃Sn), which creates a robust solder-to-BLM interface. After the solder bumps are formed, the mask of cured photoresist is removed, leaving the substrate covered with the continuous seed layer and numerous solder bumps.

However, in order to electrically isolate the solder bumps from one another, the exposed portions of the BLM layer must then be removed in a manner that allows the bumps to remain mechanically fixed to the substrate. Generally, such metal removal may be accomplished by chemical etching, electroetching, or plasma etching. Regardless of the method used for BLM layer removal between solder bumps, the solder bump should protect the metal layers therebeneath during processing. Thereby, isolated BLM pads beneath the solder bumps are created. Finally, a solder ball can be formed by melting or reflowing, and it is then ready to join to a receiving substrate.

One particular problem associated with conventional electroetching of a Cu seed layer on wafers with deposited C4 bumps is that the undercut of the copper material under the C4 bumps following the electroetch may be on the order of about 4 to 6 microns (μm). While such degree of undercut is acceptable for certain applications, there is a need to develop a Cu seed layer etch process between C4 bumps that only produces an undercut of about 1 μm or less.

### SUMMARY

The foregoing discussed drawbacks and deficiencies of the prior art are overcome or alleviated by a solution for wet etching a copper film included within a ball limiting metallurgy (BLM) of a semiconductor device, the solution including, in an exemplary embodiment, an ammonium persulfate etching agent; a potassium sulfate passivation agent for protecting a PbSn solder material, and a pH modifier for controlling the etch rate of the copper film.

In another embodiment, a solution for wet etching a copper film included within a ball limiting metallurgy (BLM) of a semiconductor device in the presence of C4 solder bumps includes an ammonium persulfate etching agent having a concentration of about 15 grams per liter (g/l) to about 25 g/l, a potassium sulfate passivation agent for protecting a PbSn solder material used in the formation of the C4 bumps, the potassium sulfate passivation agent having a concentration of about 30 g/l to about 80 g/l, and a pH modifier for controlling the etch rate of the copper film, the pH modifier maintaining the solution at a pH of about 2.5 to about 3.5.

In still another embodiment, a method for removing a copper film included within a ball limiting metallurgy (BLM) of a semiconductor device includes subjecting the semiconductor device to a wet etch solution, the solution further comprising an ammonium persulfate etching agent having a concentration of about 15 grams per liter (g/l) to about 25 g/l, a potassium sulfate passivation agent for protecting a PbSn solder material used in the formation of C4 solder bumps, the potassium sulfate passivation agent having a concentration of about 30 g/l to about 80 g/l, and a pH modifier for controlling the etch rate of the copper film, the pH modifier maintaining the solution at a pH of about 2.5 to about 3.5; wherein the wet etch solution removes a upper copper layer of the BLM, selective to a lower TiW layer of the BLM.

### TECHNICAL EFFECTS

As a result of the summarized invention, a solution is technically achieved in which undercutting of a top copper layer of a BLM stack is reduced with respect to conventional electroetching, through a wet etch of the copper in a solution utilizing an ammonium persulfate etching agent and a potassium sulfate passivation agent for protecting a PbSn solder material.

### BRIEF DESCRIPTION OF THE DRAWINGS

Referring to the exemplary drawings wherein like elements are numbered alike in the several Figures:

FIG. 1 is a process flow diagram illustrating a method of wet etching a copper BLM layer, in accordance with an exemplary embodiment of the invention; and

FIGS. 2(a) and 2(b) are cross sectional views of an exemplary C4 solder ball connection and associated BLM thereunder, suitable for use in accordance with the method illustrated in FIG. 1.

### DETAILED DESCRIPTION

Disclosed herein is a method and product for minimizing copper layer undercut during the removal of a seed layer associated with C4 solder bump formation. Briefly stated, a chemical copper etch solution is disclosed that does not result in a significant Cu undercut under the C4 bumps. Moreover, the lead containing C4 bumps are protected by a layer of insoluble salt in the solution that prevents the loss of C4 bump material during the etch process.

The wet etching solution disclosed herein and associated reduced undercutting of the copper BLM layer is particularly desirable in certain applications, such as organic laminate packaging, where the C4 strength requirements may not be as stringent with respect to other types of packaging. In such a case, the BLM structure may be made simpler by eliminating the chrome-copper (CrCu) interface between the lower TiW BLM layer and the upper Cu BLM layer. Thus, by implementing a wet etch to remove the upper copper BLM layer, the need for electroetching of any of the BLM materials is eliminated altogether by omitting CrCu. The TiW may then subsequently also be eliminated by wet etch, such as described in, for example, U.S. Pat. No. 6,015,505, assigned to the assignee of the present application.

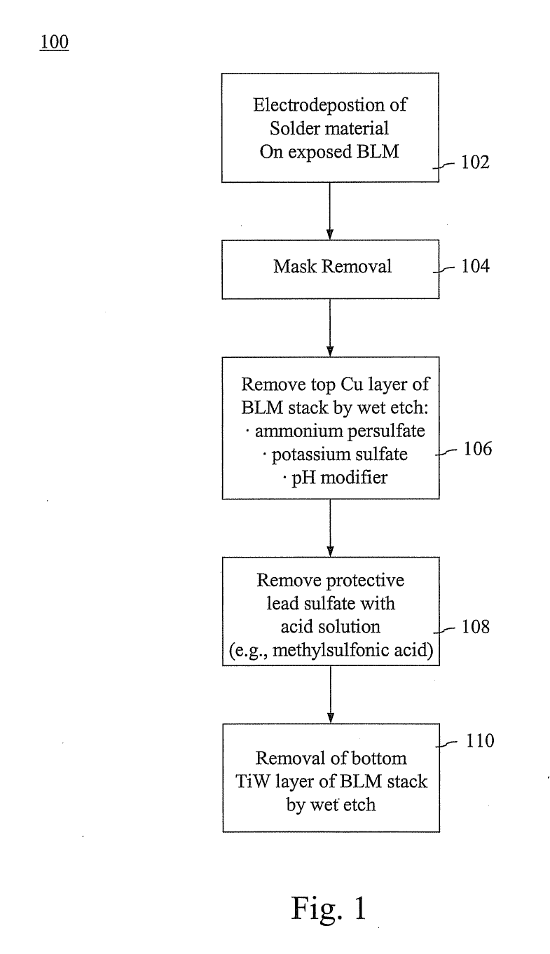

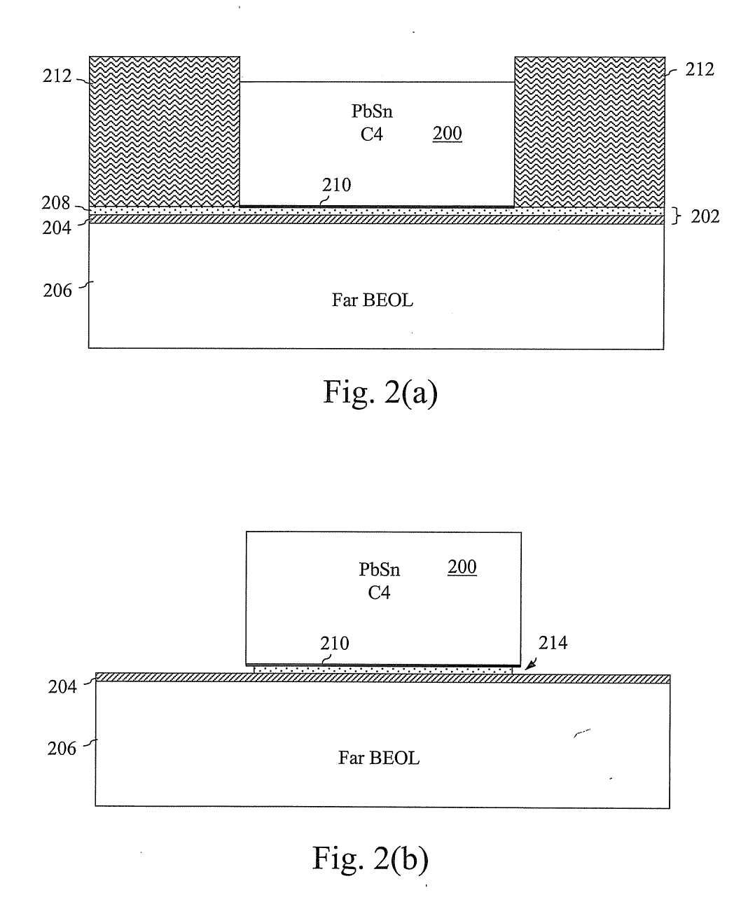

Referring to FIG. 1, there is shown a process flow diagram 100 illustrating a method of wet etching a copper BLM layer, in accordance with an exemplary embodiment of the invention. As initially shown in block 102 of FIG. 1, C4 solder bumps may be fabricated by electroplating solder material onto exposed portions of the BLM material (e.g., through a pattern photoresist material). FIG. 2(a) is a cross sectional view of an exemplary plated C4 solder connection 200 formed by electrodeposition, and before reflow of the same. In the exemplary embodiment shown therein, a BLM 202 includes a lower TiW layer 204 formed over a substrate 206, and an upper copper layer 208 formed directly upon the TiW layer 204. Again, in the exemplary embodiment depicted, the use of an intermediate CrCu layer is omitted from the BLM stack 202. In addition, a barrier layer 210 (e.g., nickel) may also be formed on the exposed portion of the BLM stack 202 following the patterning of resist layer 212 and prior to the deposition of the solder ball 200.

Referring again to FIG. 1, following C4 solder ball deposition, the mask of resist 212 is removed, as shown in block 104. Then, the upper copper layer of the BLM is removed by a wet etch process, as indicated in block 106. More specifically, the substrate is etched, for example, at room temperature in a bath containing: water; an oxidizer in a form of ammonium persulfate at a concentration of about 15 to about 25 g/l (and more preferably about 18 to about 22 g/l) that etches Cu; potassium sulfate at a concentration of about 30 to about 80 g/l (and more preferably about 35 to about 45 g/l) in order to passivate PbSn C4 bumps. In addition, the etch solution is maintained at a pH of about 2.5 to about 3.5 (and more preferably about 2.9 to about 3.1), as adjusted by ammonium hydroxide or sulfuric acid adds.

The wet etch process may be implemented using a spray etch tool or immersion type tool with a resulting etch rate of the order of about 600 angstroms (Å)/minute at ambient temperature. In so doing, the etch conditions limit the degree of Cu undercut 214 to less than about 1 μm, while the C4 bump metallurgy that contains lead is protected by a layer of low solubility lead sulfate. The resulting etched Cu layer 208 is depicted in FIG. 2(b). As then shown in block 108 of FIG. 1, the resulting passivating layer of lead sulfate may be removed following the wet Cu etch by immersion in an acid solution, such as methylsulfonic acid, for example. However, it will be noted that in contrast to passivating etches of other metals with other etchant solutions (e.g., hydrogen peroxide for etching TiW), application of the present solution results in the absence of a crust formation of lead sulfate.

Finally, as shown in block 110, the remaining TiW layer 204 of the BLM stack 202 may then be removed, such as through another wet etch process directed to removing TiW. It should appreciated that although the wet Cu etching solution disclosed herein is presented in terms of its application to removing the Cu portion of a BLM stack in the presence of C4 solder balls, it is further contemplated that the solution is equally applicable to other configurations that generally involve wet etching in the presence of corrodible structures.

While the invention has been described with reference to a preferred embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A solution for wet etching a copper film included within a ball limiting metallurgy (BLM) of a semiconductor device, comprising:
an ammonium persulfate etching agent;
a potassium sulfate passivation agent for protecting a PbSn solder material; and
a pH modifier for controlling the etch rate of the copper film.

2. The solution of claim 1, wherein the BLM comprises the copper film formed directly upon a TiW layer, without the presence of a CrCu layer therebetween.

3. The solution of claim 1, wherein the pH modifier comprises ammonium hydroxide.

4. The solution of claim 1, wherein the pH modifier comprises sulfuric acid.

5. The solution of claim 1, wherein the concentration of the ammonium persulfate etching agent is about 15 grams per liter (g/l) to about 25 g/l.

6. The solution of claim 1, wherein the concentration of the potassium sulfate passivation agent is about 30 grams per liter (g/l) to about 80 g/l.

7. The solution of claim 1, wherein the pH modifier maintains the solution at a pH of about 2.5 to about 3.5.

8. A solution for wet etching a copper film included within a ball limiting metallurgy (BLM) of a semiconductor device in the presence of C4 solder bumps, the solution comprising:
an ammonium persulfate etching agent having a concentration of about 15 grams per liter (g/l) to about 25;
a potassium sulfate passivation agent for protecting a PbSn solder material used in the formation of the C4 bumps, the potassium sulfate passivation agent having a concentration of about 30 g/l to about 80 g/l; and
a pH modifier for controlling the etch rate of the copper film, the pH modifier maintaining the solution at a pH of about 2.5 to about 3.5.

9. The solution of claim 8, wherein the pH modifier comprises ammonium hydroxide.

10. The solution of claim 8, wherein the pH modifier comprises ammonium hydroxide.

11. The solution of claim 8, wherein the concentration of the ammonium persulfate etching agent is about 18 grams per liter (g/l) to about 22 g/l.

12. The solution of claim 8, wherein the concentration of the potassium sulfate passivation agent is about 35 grams per liter (g/l) to about 45 g/l.

13. The solution of claim 8, wherein the pH modifier maintains the solution at a pH of about 2.9 to about 3.1.

14. A method for removing a copper film included within a ball limiting metallurgy (BLM) of a semiconductor device, comprising:
subjecting the semiconductor device to a wet etch solution, the solution further comprising an ammonium persulfate etching agent having a concentration of about 20 grams per liter (g/l), a potassium sulfate passivation agent for protecting a PbSn solder material used in the formation of C4 solder bumps, the potassium sulfate passivation agent having a concentration of about 80 g/l, and a pH modifier for controlling the etch rate of the copper film, the pH modifier maintaining the solution at a pH of about 3.0;
wherein the wet etch solution removes a upper copper layer of the BLM, selective to a lower TiW layer of the BLM.

15. The method of claim 14, wherein the BLM comprises the upper copper film formed directly upon the lower TiW layer, without the presence of a CrCu layer therebetween.

16. The method of claim 14, wherein the pH modifier comprises ammonium hydroxide.

17. The solution of claim 14, wherein the pH modifier comprises sulfuric acid.

18. The method of claim 14, further comprising removing lead sulfate following application of the wet etch solution.

19. The method of claim 18, wherein the lead sulfate is removed by immersing the semiconductor device in a methylsulfonic acid solution.

20. The method of claim 14, wherein the upper copper layer is etched at a rate of about 600 angstroms (Å)/minute at ambient temperature.
